(19) United States
(12) Patent Application Publication
(10) Pub. No.: US 2006/0239381 A1
(43) Pub. Date: Oct. 26, 2006

(54) METHODS AND APPARATUS FOR ROBUST AND LOW-COMPLEXITY QAM MODULATION

(75) Inventors: Doron Burshtein, Ramat Efal (IL); Ofir Shalvi, Herzlia (IL)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/456,227

(22) Filed: Jul. 10, 2006

Related U.S. Application Data
(62) Division of application No. 09/778,221, filed on Feb. 6, 2001, now abandoned.
(63) Continuation of application No. 09/437,189, filed on Nov. 9, 1999, now abandoned.
(60) Provisional application No. 60/107,628, filed on Nov. 9, 1998.

(51) Int. Cl. H04L 27/36; H03D 1/24

(52) U.S. Cl. 375/298; 375/320

(57) ABSTRACT

The present invention provides low complexity methods and apparatus for improving the performance of conventional QAM modulations. These methods provide (a) larger noise margins than conventional constellations and/or (b) improved labeling schemes. Additionally, the invention provides fixed-print approximations of these constellations to allow for low complexity VLST implementations of these schemes.

This application claims priority under 35 USC § 119(e)(1) of Provisional Application Ser. No. 60/107,628, filed Nov. 9, 1998; this application is a continuation of application Ser. No. 09/437,189, filed Nov. 9, 1999; and this application is a divisional of application Ser. No. 09/778,221, filed Feb. 6, 2001.

### TECHNICAL FIELD OF THE INVENTION

The present invention relates to QAM modulation and more particularly, to method and apparatus for robust and low complexity QAM modulation.

### BACKGROUND OF THE INVENTION

Conventional QAM constellations typically consist of points in a square grid. These conventional QAM constellations are often complex for a certain level of performance. Thus, there is a need for reduced complexity QAM constellations that still provide good performance.

### SUMMARY OF THE INVENTION

The present invention provides low complexity methods and apparatus for improving the performance of conventional QAM modulations. These methods provide (a) larger noise margins (dₘᵢₙ²/Eₛ ratio) than conventional constellations and/or (b) improved labeling schemes. Additionally, the invention provides fixed-point approximations of these constellations to allow for a low complexity VLSI implementation of these schemes.

The present invention provides method and apparatus for robust and low complexity QAM modulation that is based on a class of floating point QAM constellation that have certain advantages in terms of robustness to noise in terms of blind eualization. The present invention provides an efficient implementation of a QAM transmitter using fixed point QAM constellations that approximate floating point constellation implementations. The QAM constellations of the present invention are particularly useful for VDSL and CATV upstream transmission.

The present invention provides QAM constellations that are designed for allowing fast convergence of blind equalization algorithms, and achieving large dₘᵢₙ²/Eₛ ratio, using non-square grids, particularly for DSL or CATV channels. These constellation deviate from conventional square grid or PSK constellations.

Conventional QAM constellations consist of points in a square grid. The constellation points of the present invention are from non-square grids and are used to achieve higher noise margins, which allow lower bit error rates for a given signal to noise ratio. Constellations for 8QAM, 13QAM and 19QAM are described, but the method may be extended to higher order constellations. Some of these constellations have advantages in terms of convergence rate of blind equalizers. Fixed-point approximations (2×4 bits and 2×5 bits) allow low-complexity implementations of the hexagonal grid 8QAM constellation in a VLSI design.

The present invention provides efficient QAM modulation implementations by allowing implementation of non square grid constellations using low word width calculations.

The present invention provides shell mapping applied in conjunction with the proposed QAM constellations allowing improvement in noise margins.

The present invention provides a blind receiver applied in conjunction with the QAM constellations that exploits the benefits of the QAM constellations in terms of convergence rate.

Additionally, two labeling schemes for QAM constellations are provided. These schemes improve the bit error rate of these constellations. One scheme is a quasi-Gray labeling for “double square” (DS) 32QAM constellation. This scheme has only 6 violations of the Gray coding. The second scheme improves the performance of Trellis Coded Modulations (TCM) with QAM constellations. The improvement is achieved by labeling the constellation points such that the number of erroneous bits in an error event is minimized by an efficient labeling scheme.

The present invention provides an efficient quasi-Gray coding for double-square 32QAM constellation.

The present invention provides an efficient labeling scheme for the uncoded bits in QAM constellations used in Trellis Coded modulation to improve the error performance of the resulting symbol.

### BRIEF DESCRIPTION OF THE DRAWINGS

For a more complete understanding of the present invention, and the advantages thereof, reference is now made to the following detailed description taken in conjunction with the accompanying drawings, in which:

FIG. 1A depicts a block diagram of a transmitter implementing a constellation of the present invention and FIG. 1B depicts a block diagram of a receiver implementing an equalization algorithm and slicer of the present invention.

FIG. 2 depicts the SNR required by conventional 16-QAM and 8-PSK modulation schemes (denoted by ‘*’) and the SNR required when using shell mapping with a 13-QAM constellation of the present invention and with a 19-QAM constellation of the present invention that has been obtained by an extension of the hexa-grid constellation of the present invention, as denoted by ‘o’.

FIG. 3 depicts quasi-Gray coding for double square 32QAM constellation.

FIG. 4 depicts a labeling scheme for the uncoded bits of QAM symbols used with Trellis Coded Modulation.

### DETAILED DESCRIPTION

The present invention provides method and apparatus for robust and low complexity QAM modulation that is based on a class of floating point QAM constellations that have certain advantages in terms of robustness to noise and in terms of blind equalization. The present invention provides an efficient implementation of a QAM transmitter using fixed point QAM constellations that approximate the floating point constellation implementations of the present invention. The QAM constellations of the present invention are particularly useful for VDSL and CATV upstream transmission.

A first 8QAM constellation is provided by the present invention that is represented, in a floating point representation, as:
{0,1,e^{2πj/7},e^{4πj/7},e^{6πj/7},e^{8πj/7},e^{10πj/7},e^{12πj/7}} (1)

A second 8QAM constellation is provided by the present invention that is represented, in floating point representation, as:
{0,1,e^{2πj/6},e^{4πj/6},e^{6πj/6},e^{8πj/6},e^{10πj/6},1+e^{2πj/6}}−(3+j\sqrt{3})/16 (2)

A 13QAM constellation is also provided by the present invention which is represented, in floating point representation, as:
{0,±1,e^{±2πj/6},e^{±4πj/6},±1±e^{2πj/6},±\sqrt{3}}

The 13QAM constellation (3) may be extended to higher size constellations by using more points of the non-square grid, or hexa-grid.

The constellations of the present invention have two advantages over conventional square-grid constellations. One advantage of these constellations is an improved noise margin.

For the first constellation (1), it's noise margin may be calculated as follows; it's dₘᵢₙ=2 sin (π/7)=0.868, the symbol's power is Eₛ=⅞, and thus, dₘᵢₙ²/Eₛ=0.861 (−0.652 dB), which is better by 1.67 dB than a conventional square-grid 8-PSK.

For the second constellation (2), it's noise margin may be calculated as follows; it's dₘᵢₙ=1, Eₛ=1.078, and thus, dₘᵢₙ²/Eₛ=0.928 (−0.32 dB), which is better by 2 dB than the conventional 8-PSK.

For the 13QAM constellation (3), when it is used in conjunction with a shell mapper that maps 6 data bits into 64 pairs of elements from the 13QAM constellation, and with this mapper dₘᵢₙ=1, Eₛ=1.031, and dₘᵢₙ²/Eₛ=0.97 (−0.13 dB).

A second advantage of these constellations is faster blind convergence.

As shown in O. Shalvi and E. Weinstein, “Universal Methods for Blind Deconvolution”, in S. Haykin (Ed.), Blind Deconvolution, Prentice-Hall, 1994, the effect of the symbol constellation on the performance of a class of blind equalization algorithms, including the constant modulus algorithm (CMA), is through the efficiency factor ρ=(M₂M₆−M₄²)/C₄², where Mn is the n-th order moment of the input symbol, and where C₄ is the Kurtosis of the input symbol. When the input symbol is drawn from a constant-modulus constellation (e.g. 4-PSK and 8-PSK), ρ obtains its optimum value, which is zero; thus, PSK constellations are optimal. The advantage of the first constellation (1) of the present invention is that it attains the optimality condition ρ=0, and thus it allows optimal blind equalization performance. Another blind equalization algorithm is a super exponential algorithm.

These constellations have been discussed hereinbefore in a floating point format. However, they may be closely approximated by fixed point versions which the present invention also provides.

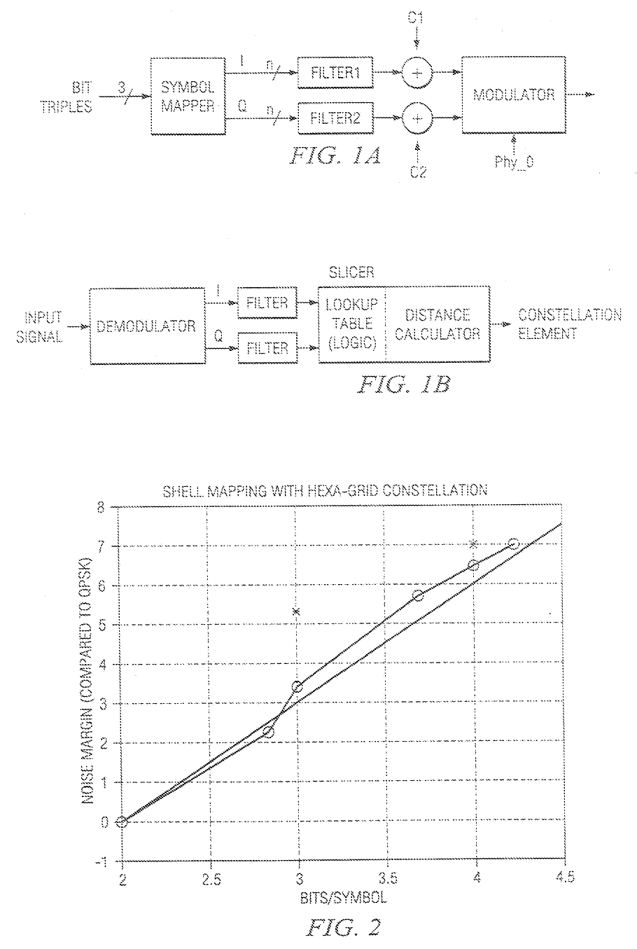

The word width of the transmitted symbols determines the complexity (word width) of the transmission filter's multiplier. The floating point constellations provided by the present invention may be approximated by a class of fixed point constellations which maintain the benefits of the hexa-grid floating point constellations but with low word widths. FIG. 1 shows a block diagram of a transmitter for implementing such a constellation.

The symbol mapper is actually a table with eight entries, containing n-bit wide I and Q components, where the implementation complexity of the filters depends the value of n. The I and the Q filters may be different from each other (e.g. by a gain factor). The addition of C1 and C2 to the outputs of the filters allows approximating the desired constellation using a low word width in the symbol mapper. The input to the modulator may be rotated by a phase offset Phy_{—}0, which also allows using a low word width, and the modulator may fix this phase offset.

The present invention provides a fixed point approximation for the constellation (1). The mapper table is
{−1, 15, 9±12j, −4±15j, −15±7j}, (4)
This mapper can be implemented with 5 bits for the I and Q axis. The I and Q filters are identical (for example, both equal to a square root raised cosine), C1=0.75*F(0), C2=0, where F(0) is the DC component of the transmission pulse filters. In this constellation dₘᵢₙ²=178, the symbol's power is Eₛ=213.25, and dₘᵢₙ²/Eₛ=0.835 (−0.785 dB). The efficiency factor of this constellation is ρ=-0.0142, and thus the blind equalization performance of this fixed point constellation is nearly optimal.

The following is a fixed point approximation of constellation (2). The mapper is:
{, 1±j, −1±j, 2, −2, 3+j}, (5)
This mapper can be implemented with 3 bits for the I axis and 2 bits for Q axis. The I filter is a square-root raised cosine filter, the Q filter is the product of the I filter by \sqrt{3}, C1=⅜* F(0), and C2=\sqrt{3/8}* F(0). In a similar manner, the constellation (3) may be approximated by a fixed point implementation.

The following is an alternative fixed point implementation of constellation (2). The mapper is:
{−8−2j 8−2j 4+5j −4−9j −4+5j 4−9j 12 j −2j} (6)
This mapper can be implemented with 5 bits for the I and Q axis. The advantage of this mapper (6) is that it does not require different scaling for the I and Q filters, and that its DC level is very small (30.5 dB below the average energy), thus the addition of C1 and C2 can be avoid. In this constellation dₘᵢₙ²=64, the symbol's power is Eₛ=70, and dₘᵢₙ²/Eₛ=0.914 (−0.39 dB), i.e., 0.07 dB loss compared to the floating point implementation of (2).

The following is another alternative fixed point implementation of constellation (2). The mapper is:
{−8−4j, −2−4j, 4−4j, 5+j, 1+j, 7+j, −2+6j, 4+6j} (7)
This mapper can be implemented with 4 bits for the I and Q axis. The advantage of this mapper is that it does not require different scaling for the I and Q filters, and that its DC level is also very small (24 dB below the average energy), thus the addition of C1 and C2 can be avoided. In this constellation dₘᵢₙ²=34, the symbol's power is Eₛ=37.75, and dₘᵢₙ²/Eₛ=0.8 (−0.45 dB), i.e., 0.13 dB loss compared to the floating point implementation of (2).

These constellations, and particularly constellation (3), are suitable for working with a shell mapper that receives k-tuples of bits and generates N symbols, where k<Mlog;(S), where S is the size of the constellation (8 or 13 in the above examples). The mapper uses the 2^{k} M-dimensional vectors of symbols that has the smallest magnitudes among all the possible S^{N} vectors.

For example, a mapper which receives k=6 bits and generates vectors of M=2 symbols using the 13-QAM constellation is useful. This mapper uses the 64 symbol pairs having the lowest power among the possible 169 pairs, that is 1 vector of zero power, 12 vectors of power 1 and 36, 12, and 3 vectors of power 2, 3, and 4 respectively. As a result, the average symbol power is 1.0312 (rather than 1.078 with constellation (2)).

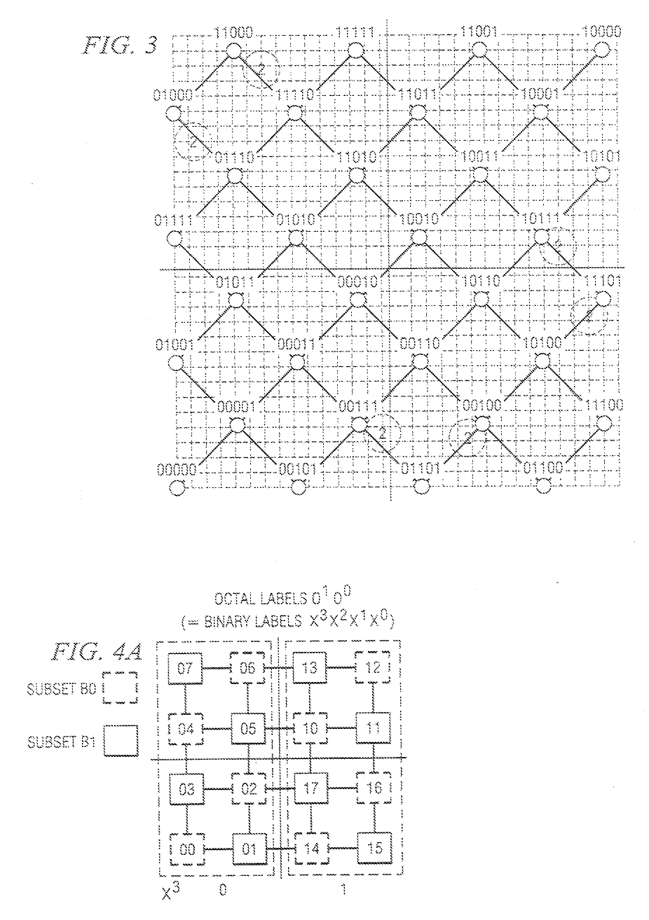

FIG. 2 shows the SNR required by a conventional 16-QAM and 8-PSK modulation schemes (denoted by ‘*’) and the SNR required when using shell mapping with the 13-QAM constellation (3) of the present invention and a 19-QAM constellation obtained by extending the hexa-grid of (3) (denoted by ‘o’).

A receiver may be employed in either a blind mode or a trained mode. If the receiver operates blindly it can be based on the CMA algorithm. Such an algorithm will have a good convergence rate and ability to converge in tough or noisy channel conditions when a modified constant modulus constellation such as (1) is used.

The slicer in such a receiver will have two stages:
1. a pre-programmed lock-up-table (or logic) receiving I and Q components and generating indexes of 1-3 constellation elements.
2. a distance calculator which calculates the Euclidean distance from the slicer input to the constellation elements pointed out by the look-up-table. This may be implemented with an adder and an x² unit (which is less complex than a multiplier for a VLSI design).

The slicer will output the constellation element having the smallest distance to its input. A block diagram of a receiver employing the slicer of the present invention is depicted in FIG. 1.

The present invention also provides a quasi-Gray coding scheme for a “double-square” (DS) 32QAM constellation. A DS 32 QAM constellation and the coding scheme are depicted in FIG. 3. DS constellations have been proposed for 8QAM, 32QAM and 128QAM for use in next generation DOCSIS specifications for CATV plants. In these constellations, the constellation points are evenly distributed within a square (unlike the more common cross QAM constellations). This allows better performance with a Tomlinson-Harashima precoder. It can be proven that Gray coding (i.e., labeling the constellation points such that the Hamming distance between each neighboring pairs is one) of a DS 32QAM constellation is not possible. The invention provides a labeling scheme with only 6 violations of Gray code (with Hamming distance of 2 in each violation). This is believed to be the minimal possible number of violations. For all violations, the 2 bits are located in adjacent locations in the label, thus minimizing the byte error rate (there is high probability that in an error event the two erroneous bits would fall into the same byte)

When Tomlinson-Harashima precoding is used, the points on the external boundaries of the constellation have additional neighbors due to the modulo operation of the precoder. The labeling scheme of the present invention is believed to provide the minimal number of Gray-code violations with the minimal Hamming distance in each violation as shown in the following table:

| | pairs with | “TH modulo” |
|---|---|---|
| Hamming | violations | pairs with |
| Distance | (without TH) | violatons |
| 1 | 43 | 1 |
| 2 | 6 | 6 |
| 3 | 0 | 6 |
| 4 | 0 | 2 |
| 5 | 0 | 0 |

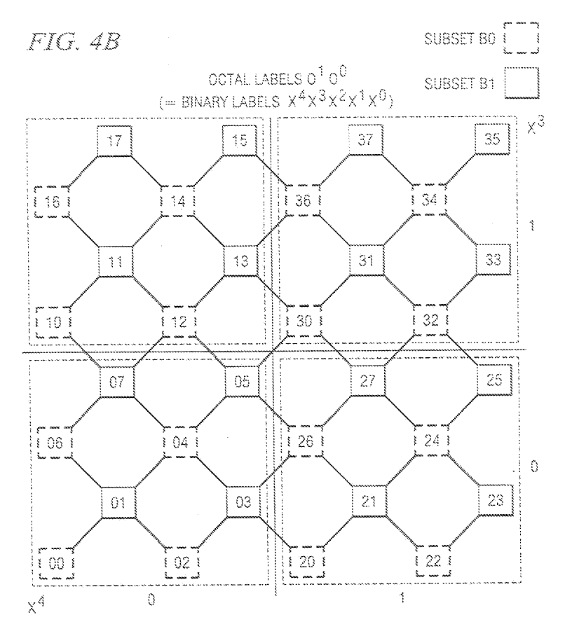

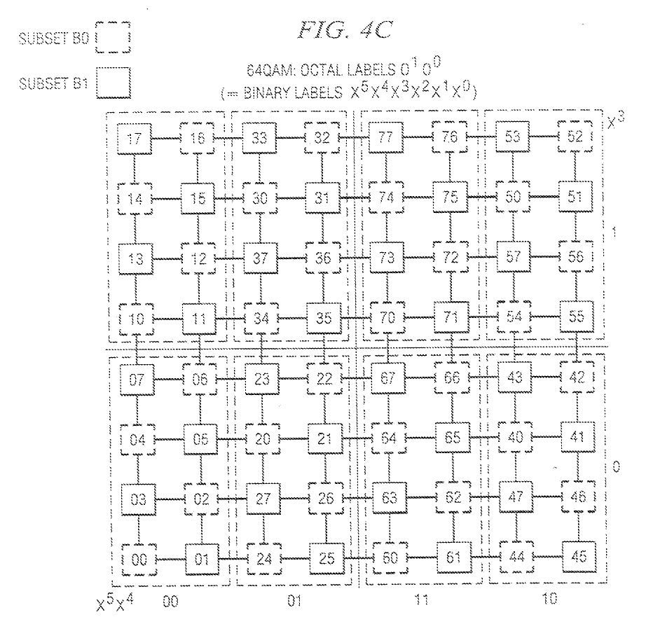

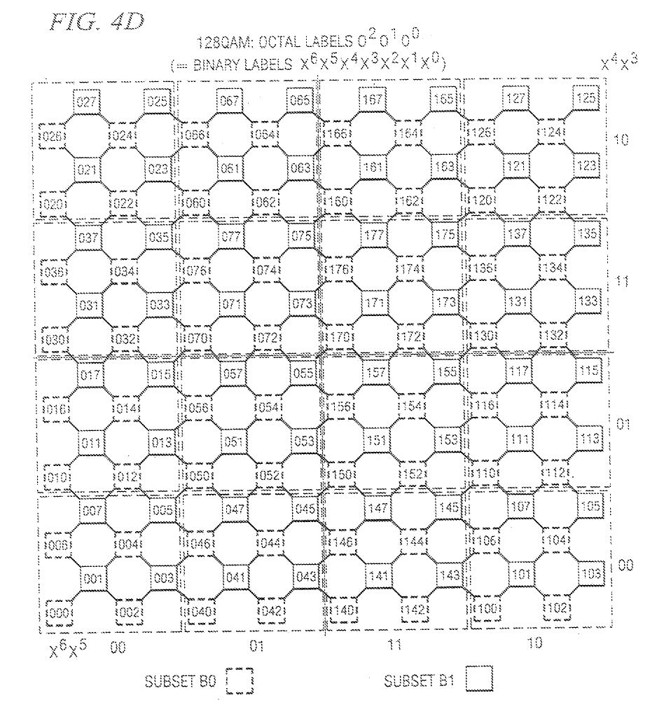

The invention also provides an efficient labeling scheme for QAM constellations used in Trellis Coded Modulation (TCM) as depicted in FIG. 4. This labeling scheme improves the error performance of the uncoded and coded bits of the coded. The error performance of the uncoded bits is improved by dividing the constellation plans into 2ˆM rectangular zones (M is the number of uncoded bits per symbol). In each zone all uncoded bits are identical. The uncoded bits (i.e. the labels of the above zones) are coded using a Gray code. This labeling significantly reduces the number of errors in uncoded bits in a dₘᵢₙ error event.

When the symbols are interleaved (or when the uncoded subsymbols are interleaved as in the IEEE802.14a specification draft), there is also a significant decrease in byte error rate because each uncoded subsymbol of an error event belongs to a different byte. Therefore, reducing the subsymbol error probability directly reduces the byte error probability. For example, for 64QAM, and the TCM scheme proposed for the IEEE802.14a specification, the average erroneous bytes per error event (due to uncoded subsymbols) reduces from 2.6 to 1.4.

The error performance of the coded bits is improved by minimizing the Hamming distance between the source bits of the coded bits neighboring points along the constellation boundaries. For example, in the 16QAM constellation of FIG. 4, the source bits of the coded bits of point 15 (hex) are 10 (binary). The Hamming distance between the source bits of this point and its two neighboring points is 0 (point 14, source bits: 10) and 1 (point 16, source bits: 11). Therefore, when this point is transmitted, and an error event occurs, there will be 0 or 1 (out of 2) erroneous coded bits. This modification slightly reduces the bit error rate at the TCM decoder output.

The present invention is capable of being implemented in software, hardware, or combinations of hardware and software. Although the present invention and its advantages have been described in detail, it should be understood that various changes, substitutions and alterations may be made herein without departing from the spirit and scope of the invention, as defined in the appended claims.

1. A transmitter, comprising:
a symbol mapper for receiving inputs,
a filter for each output of said matter, and
a modulator for receiving said filter's outputs and providing an output signal.

2. The transmitter of claim 4, wherein said mapper employs a non-square grid QAM constellation.

3. A slicer for a receiver, comprising:
a pre-programmed look-up-table for receiving I and Q components and generating indexes of n constellation elements, and
a distance calculator which calculates the Euclidean distance from a slicer input to the n constellation elements pointed to by the look-up-table to determine the constellation element to be output.

4. The slicer of claim 6, wherein said distance calculator employs an adder and squaring unit.

5. A receiver, comprising:
a demodulator for receiving an input signal and outputting a data stream,
a filter for said data stream, and
a slicer for converting said data stream to a constellation point.

6. The receiver of claim 8, wherein said receiver is a blind receiver employing a super exponential algorithm or a CMA.

7. The receiver of claim 9, wherein said constellation points are selected from {0,1,e^{2πj/7},e^{4πj/7},e^{6πj/7},e^{8πj/7},e^{10πj/7},e^{12πj/7}}.
